(19) United States
(12) Patent Application Publication
(10) Pub. No.: US 2025/0326001 A1
(43) Pub. Date: Oct. 23, 2025

(54) FILM FORMING APPARATUS, FILM FORMING METHOD, AND MANUFACTURING METHOD OF ARTICLE

(71) Applicant: CANON KABUSHIKI KAISHA, Tokyo (JP)

(72) Inventor: YUSHI YAMAKAWA, Tochigi (JP)

(21) Appl. No.: 19/170,485

(22) Filed: Apr. 4, 2025

(30) Foreign Application Priority Data
Apr. 19, 2024 (JP) 2024-068027

(51) Int. Cl. B05C 13/00; B05C 9/12; B05C 11/00

(52) U.S. Cl. CPC B05C 13/00; B05C 9/12; B05C 11/00

(57) ABSTRACT

A film forming apparatus configured to form a film of a curable composition on a substrate. The film forming apparatus comprises a holding unit configured to hold the substrate, a light irradiation unit configured to irradiate light that cures the curable composition, a drive unit configured to drive so as to change a relative position between the holding unit and the light irradiation unit, and a control unit configured to control driving of the drive unit and timing at which the light irradiation unit irradiates the light based on an illuminance distribution of the light in a region in which the light is irradiated by the light irradiation unit.

### BACKGROUND OF THE INVENTION

### Field of the Invention

The present invention relates to a film forming apparatus, a film forming method, and a manufacturing method of an article.

### Description of the Related Art

A technology of planarizing a resin dropped on a substrate by using a flat mold (also referred to as a “template” or a “superstrate”) has been proposed (Please refer to Japanese Patent No. 5,349,588.). The technology disclosed in Japanese Patent No. 5,349,588 aims to improve the accuracy of planarization by dropping a curable composition in which a dropping amount is adjusted based on the concave-convex structure of a substrate, and curing the composition in a state in which a flat template is in contact with the dropped composition. Examples of the means for curing the composition include irradiation with ultraviolet rays. In a case in which the illuminance distribution of the light reaching the composition is uneven, the curing of the composition becomes uneven, which may ultimately result in insufficient planarization.

In Japanese Patent Application Laid-Open No. 2020-167345, a light emitting element array having a plurality of light emitting elements that are arranged two dimensionally is used as a light source. Light emitted from the light source is guided to the composition through an optical member. In general, regardless of whether the light source is formed of a single light emitting element or a plurality of light emitting elements, the illuminance distribution of light emitted from the light source is not uniform. Therefore, in Japanese Patent Application Laid-Open No. 2020-167345, the illuminance distribution of the light that is guided to the composition is made uniform by locally changing the reflectance or the ease of diffusion of the optical element.

In Japanese Patent Application Laid-Open No. 2021-135504, collimated light that has been emitted to cure a composition is passed through a diffusing element to be diffused. As a result, variations in transmittance of the collimated light due to non-uniform geometric features of a template chuck is reduced.

As described above, because the uniformity of the illuminance distribution irradiated onto the composition affects the planarization performance, it is necessary to make the illuminance distribution uniform. However, in Japanese Patent Application Laid-Open No. 2020-167345 and Japanese Patent Application Laid-Open No. 2021-135504, although the illuminance distribution is made uniform by shaping the light emitted from the light source, the illuminance distribution of the light is not necessarily made uniformed.

### SUMMARY OF THE INVENTION

Therefore, an embodiment of the present invention provides a technology that is advantageous in reducing uneven illuminance.

A film forming apparatus according to an aspect of the present invention is a film forming apparatus configured to form a film of a curable composition on a substrate, comprising: a holding unit configured to hold the substrate; a light irradiation unit configured to irradiate light that cures the curable composition; a drive unit configured to drive so as to change a relative position between the holding unit and the light irradiation unit; and a control unit configured to control driving of the drive unit and timing at which the light irradiation unit irradiates the light based on an illuminance distribution of the light in a region in which the light is irradiated by the light irradiation unit.

Further features of the present invention will become apparent from the following description of exemplary embodiments with reference to the attached drawings.

### BRIEF DESCRIPTION OF THE DRAWINGS

FIG. 1 is a schematic view illustrating a configuration example of a film forming apparatus of the first embodiment.

FIG. 2 is a schematic view illustrating a laminate.

FIGS. 3A to 3C are diagrams illustrating a first example of illuminance distribution, control of relative motion between the holding unit and the light irradiation unit, and timing of light irradiation.

FIGS. 4A to 4D are diagrams illustrating a second example of illuminance distribution, the control of relative motion between the holding unit and the light irradiation unit, and timing of light irradiation.

FIGS. 5A to 5D are diagrams illustrating a third example of the illuminance distribution, control of relative motion between the holding unit and the light irradiation unit, and timing of light irradiation.

FIGS. 6A to 6E are diagrams illustrating a fourth example of the illuminance distribution, control of relative motion between the holding unit and the light irradiation unit, and timing of light irradiation.

FIG. 7 is a flowchart illustrating an example of a process in the film forming apparatus.

FIG. 8 is a flowchart illustrating details of a profile determination step.

FIG. 9 is a flowchart illustrating details of a forming step.

FIG. 10 is a flowchart illustrating details of an illuminance distribution acquisition step P3.

FIG. 11 is a schematic view illustrating a configuration example of a film forming apparatus of the second embodiment.

FIG. 12 is a schematic view illustrating a configuration example of the film forming apparatus of the third embodiment.

FIGS. 13A to 13F are diagrams for explaining a manufacturing method of an article.

### DESCRIPTION OF THE EMBODIMENTS

Hereinafter, preferred embodiments of the present invention will be explained in detail with reference to the accompanying drawings.

### First Embodiment

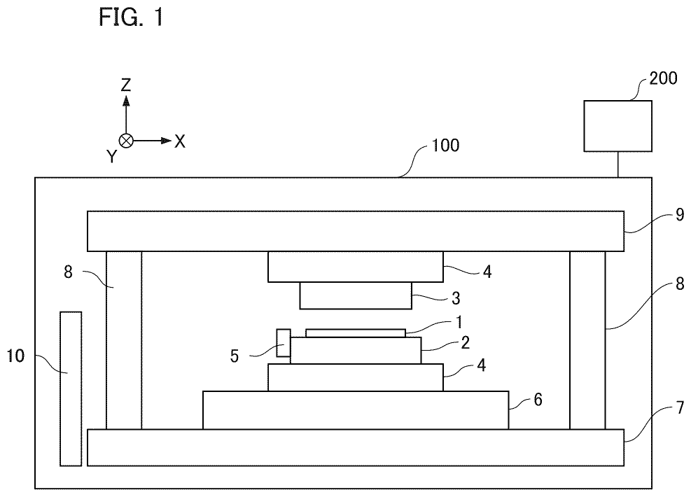

FIG. 1 is a schematic view illustrating a configuration example of a film forming apparatus 100 of the first embodiment. In the present specification and the drawings, directions are indicated in an XYZ coordinate system in which a horizontal plane is an XY plane. In general, a substrate 1a, which is an object to be processed, is placed on a holding unit 2 so that the surfaces thereof are parallel to the horizontal plane (XY plane). Therefore, hereinafter, directions orthogonal to each other in a plane along surface of the substrate 1a are defined as an X-axis and a Y-axis, and a direction perpendicular to the X-axis and the Y-axis is defined as a Z-axis. Additionally, hereinafter, in the XYZ coordinate system, a direction parallel to the X axis is referred to as the X direction, a direction parallel to the Y axis is referred to as the Y direction, and a direction parallel to the Z axis is referred to as the Z direction, and a rotational direction around the X axis is referred to as the OX direction, a rotational direction around the Y axis is referred to as the OY direction, and a rotational direction around the Z axis is referred to as the OZ direction.

As shown in FIG. 1, the film forming apparatus 100 includes the holding unit 2 configured to hold a laminate 1, a light irradiation unit 3, a drive unit 4, an illuminance measurement unit 5, a first surface plate 6, a base 7, a first support column 8, and a second surface plate 9. The film forming apparatus 100 further includes a member conveying unit 10 and a control unit 200.

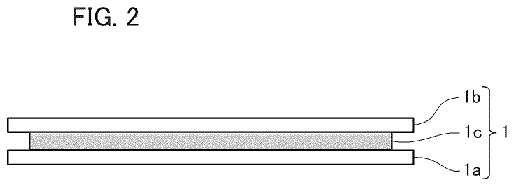

First, the laminate 1 will be explained. FIG. 2 is a schematic view illustrating the laminate 1. As shown in FIG. 2, the laminate 1 includes a substrate 1a, a template 1b, and a composition 1c. The composition 1c is formed by the template 1b after being disposed (supplied) on a surface of the substrate 1a.

The composition 1c is a formable material, for example, a curable composition that is cured when light is irradiated, such as a UV curable liquid. As the UV curable liquid, monomers such as acrylate and methacrylate may typically be used. The curable composition may be referred to as a formable material. The composition may contain any of a polymerizable compound, a photopolymerization initiator, a non-polymerizable compound, and a solvent, and may contain at least any of a sensitizer, a hydrogen donor, an internal release agent, a surfactant, an antioxidant, and a polymer component as the non-polymerizable compound. The composition of the present embodiment is cured by, for example, irradiation with light having wavelengths of 200 to 380 nm (ultraviolet light). The composition is cured by being irradiated with ultraviolet rays. However, the composition 1c is not limited thereto, and may be cured by electromagnetic waves other than ultraviolet light.

For example, glass, ceramics, metals, semiconductors, and resins can be used as the material of the substrate 1a. If necessary, a member made of a material different from that of the substrate may be provided on the surface of the substrate. The substrate is, for example, a silicon wafer, a compound semiconductor wafer, and quartz glass. Additionally, the substrate may be a glass substrate for manufacturing a replica mask from a master mask by an imprint process.

The template 1b has a surface in contact with the composition 1c, and is a member (forming member) for forming the composition 1c so as to follow the contact surface by bringing the composition 1c into contact therewith. The template 1b is preferably a member having a flat surface that serves as a contact surface, which is referred to as a superstrate, but may be a member having a concave-convex pattern on the contact surface, such as an imprint mold. Additionally, the template 1b may be configured by a light transmissive material in consideration of a process of irradiating the composition 1c on the substrate 1a with light for curing the composition 1c. In a case in which the template 1b is a superstrate, the template 1b is configured by materials such as quartz or borosilicate glass wafers that have a flat surface of a size similar to that of the substrate, and may have a thickness in the range of, for example, 0.3 mm to 1.0 mm.

Next, main members provided in the film forming apparatus 100 will be explained with reference to FIG. 1. The member conveying unit 10 includes a conveying hand and the like and delivers the laminate 1 from a position (not illustrated) outside or inside the film forming apparatus 100 to the holding unit 2.

The holding unit 2 holds the laminate 1 including the substrate 1a, a composition 1c that is supplied onto the substrate 1a, and the template 1b that abuts on the composition 1c. Although the holding unit 2 holds the laminate 1, for example, by vacuum suction, the holding means is not limited thereto. The holding means may be, for example, electrostatic adsorption or clamping.

The light irradiation unit 3 has at least one light source, generates light having wavelengths at which the composition 1c is cured, and irradiates the composition 1c that is formed by the template 1b with light. Accordingly, the composition 1c is cured in conformity with the shape of the template 1b. The light source may be a UV lamp, a UV LED, and the like. The light sources may be arranged in a concentrated manner at one place or may be arranged uniformly in a certain plane including a curved surface, or may be arranged in a lattice shape, a stripe shape, or an annular shape, but the arrangement is not limited thereto. In general, the illuminance distribution of light emitted by the light sources such as a UV lamp and a UV LED is not uniform, and a plurality of optical elements may be used to make the illuminance distribution uniform. As the optical element to be used, a fly-eye lens, a diffuser, and the like are conceivable. Although these optical elements and other optical elements such as mirrors may be configured in the light irradiation unit 3, they are not necessarily required in the present embodiment.

The holding unit 2 is connected to the first surface plate 6 via the drive unit 4 and the light irradiation unit 3 is connected to the second surface plate 9 via the drive unit 4. Alternatively, only one of the holding unit 2 and the light irradiation unit 3 may be connected to the drive unit 4. That is, in a case in which only the holding unit 2 is connected to the drive unit 4, the light irradiation unit 3 is fixed to the second surface plate 9, and in a case in which only the light irradiation unit 3 is connected to the drive unit 4, the holding unit 2 is fixed to the first surface plate 6.

The drive unit 4 is configured to include, for example, an actuator such as a linear motor, a rotary motor, or a voice coil motor, a ball screw, a linear guide, a cam, a crank, and the like, and relatively drives both or one of the holding unit 2 and the light irradiation unit 3. The drive unit 4 performs driving for changing the relative position between the holding unit 2 and the light irradiation unit 3. Specifically, for example, the drive unit 4 is preferably configured to allow at least one of the holding unit 2 and the light irradiation unit 3 to perform at least one of translational motion in the X direction, translational motion in the Y direction, and rotational motion around the Z axis. Furthermore, the drive unit 4 may be configured to allow at least one of the holding unit 2 and the light irradiation unit 3 to perform a rotational motion around the X axis or the Y axis or a translational motion in the Z direction.

The illuminance measurement unit 5 can be fixed to the holding unit 2. The illuminance measurement unit 5 scans directly below the light irradiation unit 3 by the driving of the drive unit 4 and measures the illuminance distribution of the light emitted by the light irradiation unit 3. The illuminance measurement unit 5 may be configured by a single illuminance measurement device or may be configured by a plurality of illuminance measurement devices. Note that in a case in which the illuminance measurement unit 5 includes a drive unit and is independently movable on the first surface plate 6, the illuminance measurement unit 5 does not need to be fixed to the holding unit 2. The illuminance measurement unit 5 is necessary in a case in which the illuminance distribution is measured in the film forming apparatus 100, for example, during the operation of the film forming apparatus 100. Therefore, in a case in which the illuminance distribution is estimated by another method to be described below, the illuminance measurement unit 5 may not be configured in the film forming apparatus 100.

The control unit 200 includes a processor such as a CPU, a storage unit such as a RAM, a ROM, or an HDD, and an interface unit for connecting an external device and the processor. The interface unit also includes a communication interface that communicates with a host computer. The host computer is, for example, a computer that controls the entire factory in which the film forming apparatus 100 is disposed or a region of the factory. The processor executes a program stored in the storage unit and controls the operation of a processing device. The control unit 200 may have a plurality of circuit boards. Additionally, all or a part of the control unit 200 may be disposed in a rack inside a chamber (housing) of the film forming apparatus 100, or may be disposed outside the chamber.

The control unit 200 controls the operation of the film forming apparatus 100. Here, the operation of the film forming apparatus 100 includes the operation of each unit, and, in particular, the irradiation of light by the light irradiation unit 3 and the operation of the drive unit 4 is controlled. The drive unit 4 may drive only the holding unit 2 that holds the laminate 1 or may drive only the light irradiation unit 3. Alternatively, the drive unit 4 may drive both the holding unit 2 and the light irradiation unit 3. At this time, the timing of light irradiation from the light irradiation unit 3 and the contents of driving performed by the drive unit 4 (relative motion between the holding unit 2 and the light irradiation unit 3) are determined based on the known illuminance distribution of the light irradiation unit 3. Note that the contents of driving may include the moving direction, rotation axis, moving timing, moving speed, and the like of the holding unit 2 and the light irradiation unit 3.

The illuminance distribution of light formed on the surface to be illuminated by the light irradiation unit 3 can be acquired by causing the illuminance measurement unit 5 that is fixed to the holding unit 2 to scan immediately below the light irradiation unit 3 by the control unit 200 that controls the operation of the drive unit 4. Additionally, the illuminance distribution of the surface to be illuminated in the film forming apparatus 100 can be estimated by performing calculation processing on the illuminance distribution that has been measured before the start of the operation of the film forming apparatus 100 or the illuminance distribution known in design. This calculation processing may be performed by the control unit 200, or the control unit 200 may receive and acquire a result of calculation performed by an external processing unit.

Additionally, as a method of estimating the illuminance distribution, there is a method of measuring the film thickness of the curable composition after curing. There is a correlation between the illuminance distribution at the time of curing and the film thickness of the curable composition after curing. Therefore, the film thickness of the curable composition that has been previously processed for film formation by the film formation apparatus 100 can be measured outside the apparatus, and the illuminance distribution can be estimated from the film thickness distribution obtained as the measurement result. In a case in which this method is adopted, the control unit 200 may receive and acquire film thickness distribution data externally, and then perform calculation processing to obtain the illuminance distribution. Additionally, this calculation processing may be performed by an external processing unit, and the control unit 200 may receive and acquire data of the illuminance distribution data obtained as a result of the calculation processing.

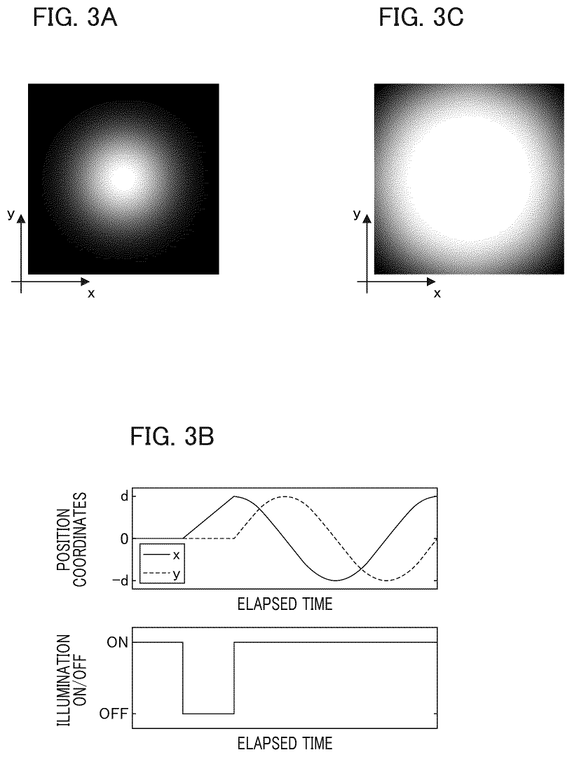

Hereinafter, the control of relative motion between the holding unit 2 and the light irradiation unit 3 and the control of the timing of light irradiation, which are determined based on the acquired illuminance distribution, will be explained below with reference to FIG. 3 to FIG. 6. In each of FIG. 3 to FIG. 6, the illuminance distribution is shown in grayscale. A white portion indicates a high illuminance, and a black portion indicates a low illuminance. That is, it is indicated that as the gray is lighter, the illuminance is higher. In the present embodiment, in the curing step, the content of driving and the irradiation timing of the light are determined so that the illumination unevenness in a region (range) of the composition 1c on the substrate 1a to be cured is reduced, preferably, such that said illumination unevenness is made uniform. That is, the content of the driving and the timing of light irradiation are determined so that the difference in the integrated light amount between an arbitrary first region and an arbitrary second region that is different from the first region among the regions on the substrate irradiated with the light is equal to or less than a predetermined value, preferably, substantially the same.

FIG. 3A to 3C are diagrams illustrating a first example of illuminance distribution, control of the relative motion between the holding unit 2 and the light irradiation unit 3, and timing of light irradiation. FIG. 3A shows a first example of the illuminance distribution. In FIG. 3A, an illuminance distribution of light formed on the surface to be illuminated in a state in which the laminate 1 (the holding unit 2) and the light irradiation unit 3 stop (a state in which there is no relative motion or no relative movement) is illustrated. In the first example, a situation in which the illuminance is distributed radially around one point, and the illuminance decreases as the radius increases is simulated. Such an illuminance distribution may occur in a case in which the light sources are arranged in a concentrated manner in one place. At this time, as shown in FIG. 3B, it is preferable to move the holding unit 2 and the light irradiation unit 3 relative to each other and switch the light source of the light irradiation unit 3 between ON and OFF. FIG. 3B shows a first example of the control of the relative motion and the timing of light irradiation. Here, the center of the illuminance distribution is set to x=0 and y=0. First, the illumination is turned ON for a predetermined time in a state in which the relative position of the laminate 1 and the light irradiation unit 3 is x=0 and y=0. Subsequently, the illumination is switched to OFF, and the laminate 1 (holding unit 2) and the light irradiation unit 3 are relatively moved to a predetermined position. In this example, the center of the laminate 1 is moved to x=d, y=0. Subsequently, the illumination is switched to ON, and at the same time, the laminate 1 is caused to perform a circular motion with a radius d around a position immediately below the center of the light irradiation unit 3. That is, in this example, light is intermittently emitted from the light irradiation unit 3. Then, a virtual illuminance distribution as shown in FIG. 3C can be obtained. In this context, although the time period during which the illumination is ON and the radius d can be arbitrarily determined, it is preferable to perform a simulation based on a known illuminance distribution and determine the time period in which the illumination is ON and the radius d so that a virtual illuminance distribution as shown in FIG. 3C becomes more uniform. That is, the time period during which the illumination is ON and the radius d may be determined so that the difference in an integrated exposure amount between an arbitrary first region and an arbitrary second region that is different from the first region among the regions on the substrate to be irradiated with light is equal to or less than a predetermined value, preferably, substantially the same. Additionally, at the same time as the circular motion, the laminate 1 may be driven in rotational motion around the Z-axis by the holding unit 2. Note that although an example in which the illuminance is radially distributed around one point has been described here, the motion of changing the relative position between the holding unit 2 and the light irradiation unit 3 may be an elliptical motion according to the shape of the illuminance distribution.

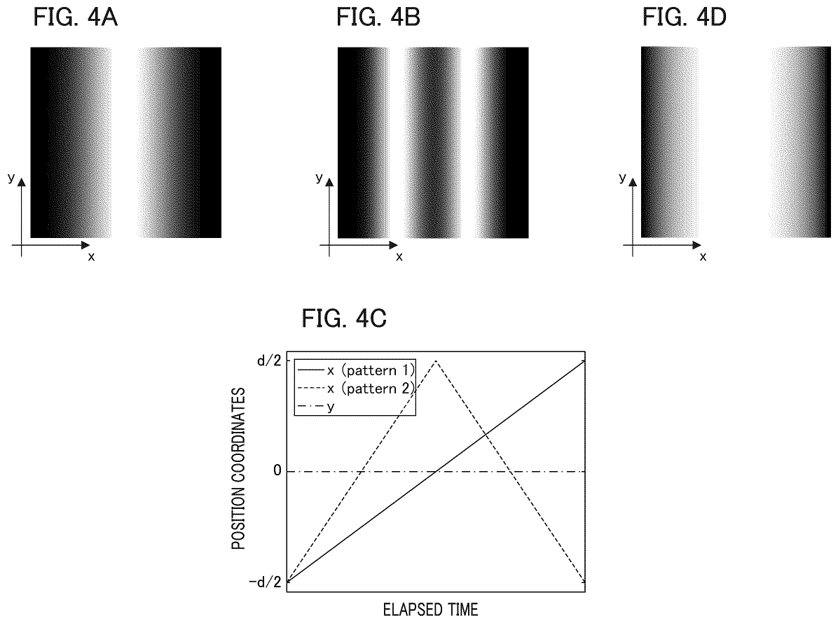

FIGS. 4A to 4D are diagrams illustrating a second example of the illuminance distribution, the control of relative motion between the holding unit 2 and the light irradiation unit 3, and timing of light irradiation. FIGS. 4A and 4B illustrate a second example of the illuminance distribution. FIGS. 4A and 4B illustrate the illuminance distribution of light formed on the surface to be illuminated in a state in which the laminate 1 (holding unit 2) and the light irradiation unit 3 stop. FIGS. 4A and 4B illustrate how the illuminance is distributed in a columnar pattern and periodically changes in the x-direction. Such an illuminance distribution can occur in a case in which the light sources are arranged on a plurality of straight lines. At this time, as shown in FIG. 4C, it is preferable to move the laminate 1 (holding unit 2) and the light irradiation unit 3 relative to each other at a constant speed in the x-direction by a distance of d in a state in which the illumination is ON. Then, a virtual illuminance distribution as shown in FIG. 4D can be obtained on the surface to be illuminated. Although the distance d is preferably set as an integer multiple of the x-direction period of the illuminance distribution, it may also be set to other values. Additionally, as indicated by the plot of pattern 2 in FIG. 4C, the motion of changing the relative position between the holding unit 2 and the light irradiation unit 3 may be a reciprocating motion. Additionally, the reciprocating motion may be repeated periodically. In this case, the movement distance in the x direction or the y direction is reduced, which is advantageous for downsizing the device.

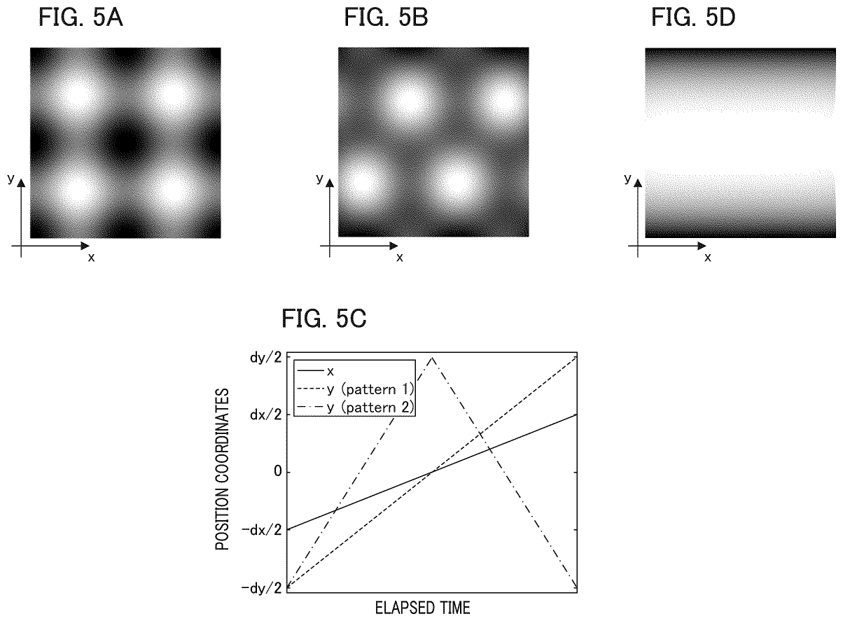

FIGS. 5A to 5D are diagrams illustrating a third example of the illuminance distribution, control of the relative motion between the holding unit 2 and the light irradiation unit 3, and timing of light irradiation. FIGS. 5A and 5B show a third example of the illuminance distribution. FIGS. 5A and 5B show the illuminance distribution of light formed on the surface to be illuminated in a state in which the laminate 1 (holding unit 2) and the light irradiation unit 3 stop. FIGS. 5A and 5B illustrate how the illumination is distributed in a manner resembling a periodic point cloud. Such an illuminance distribution may occur in a case in which the light sources are arranged uniformly in a certain plane. At this time, as shown in FIG. 5C, it is preferable to move the laminate 1 (holding unit 2) and the light irradiation unit 3 relative to each other at a constant speed by a distance dx in the x-direction and a distance dy in the y-direction in a state in which the illumination is ON. Then, a virtual illuminance distribution as shown in FIG. 5D can be obtained on the surface to be illuminated. The distance dx is preferably set as an integer multiple of the x-direction period of the illuminance distribution, and the distance dy is set as an integer multiple of the y-direction period of the illuminance distribution. At this time, it is preferable to determine dx and dy so that the laminate 1 (holding unit 2) and the light irradiation unit 3 move equal to or more than two cycles in the y-direction while moving one cycle in the x-direction. Additionally, as indicated by the plot of pattern 2, the motion of changing the relative position between the holding unit 2 and the light irradiation unit 3 may be a reciprocating motion. Additionally, the reciprocating motion may be repeated periodically. In this case, the movement distance in the x direction or the y direction is reduced, which is advantageous for downsizing the device.

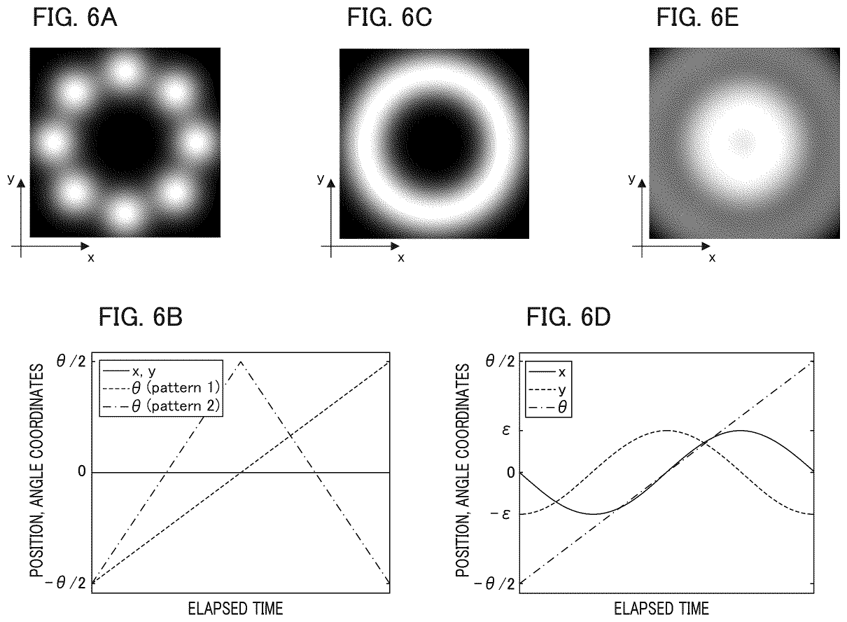

FIGS. 6A to 6E are diagrams illustrating a fourth example of the illuminance distribution, control of relative motion between the holding unit 2 and the light irradiation unit 3, and timing of light irradiation. FIG. 6A shows a fourth example of illuminance distribution. FIG. 6A shows an illuminance distribution of light formed on the surface to be illuminated in a state in which the laminate 1 (holding unit 2) and the light irradiation unit 3 stop. FIG. 6A shows how the illuminance is distributed in a manner resembling an annular point cloud. Such an illuminance distribution may occur in a case in which the light sources are arranged in an annular shape. Note that the annular point cloud does not need to be arranged periodically. At this time, as shown in FIG. 6B, it is preferable that the laminate 1 (holding unit 2) and the light irradiation unit 3 are relatively rotated by an angle θ in a state in which the illumination is ON and the central axes of the laminate 1 and the light irradiation unit 3 in the Z direction are the same. As a result, an annularly uniform virtual illuminance distribution as shown in FIG. 6C can be obtained on the surface to be illuminated. In this case, for example, in a case in which a partial region on the substrate is irradiated with light, such as in a case in which only the outer peripheral portion of the substrate is irradiated with light, illuminance unevenness in the partial region can be reduced. The angle θ is preferably set as an integer multiple of the period in a case in which the point cloud is periodically arranged, and the angle θ is preferably set as an integer multiple of 2π in a case in which the point cloud is non-periodic. Additionally, as indicated by the plot of pattern 2, the motion of changing the relative position between the holding unit 2 and the light irradiation unit 3 may be a reciprocating motion. Additionally, the reciprocating motion may be repeated periodically. Furthermore, the laminate 1 and the light irradiation unit 3 may be rotated relative to each other by the angle θ in a state in which the central axes of the laminate 1 and the light irradiation unit 3 are decentered by ε (epsilon). The relative position and the relative angle at this time are as shown in FIG. 6D. In this case, for example, a virtual illuminance distribution as shown in FIG. 6E can be obtained on the surface to be illuminated. Note that, it is also possible to obtain a circularly uniform virtual illuminance distribution on the substrate as shown in FIG. 3C by combining the motions of changing the relative positions as shown in FIG. 6B and FIG. 6D.

Although the examples of the illuminance distribution and the control of the driving of the drive unit 4 and the timing of light irradiation performed by the light irradiation unit 3 have been explained above, the illuminance distribution, the control of driving performed by the drive unit 4 and the timing of light irradiation performed by the light irradiation unit 3 are not limited thereto. The illuminance distribution may be irregular. In this case, using a computer, a virtual illuminance distribution is repeatedly calculated while varying the content of driving by the drive unit 4 and timing of light irradiation. Then, the content of driving and the timing of light irradiation may be determined so that the variation (unevenness) in the virtual illuminance distribution is reduced, preferably minimized.

As described above, it is possible to determine the content of driving of the drive unit 4 and the timing of light irradiation based on the known illuminance distribution. This calculation processing (determination processing) may be performed by the control unit 200, or the control unit 200 may receive and acquire a result of calculation performed by an external processing unit. The control unit 200 controls the operations of the light irradiation unit 3, the drive unit 4, and other components of the film forming apparatus 100 according to the determined content of the driving and the timing of light irradiation to form the composition 1c.

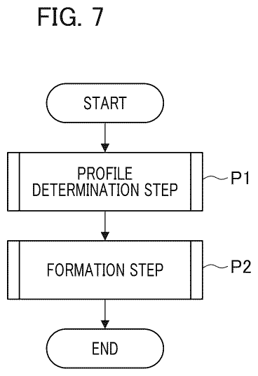

Next, a series of processes according to the present embodiment will be explained with reference to FIG. 7 to FIG. 10. FIG. 7 is a flowchart illustrating an example of a process in the film forming apparatus 100. As shown in FIG. 7, the process of forming the composition 1c using the film forming apparatus 100 described above includes a profile determination step P1 and a forming step P2.

The profile determination step P1 is a step of determining the content of driving of the drive unit 4 and the timing of light irradiation. Hereinafter, the content of driving and the timing of light irradiation will be referred to as a profile.

The forming step P2 is performed after the profile determination step P1. The forming step P2 is a step in which the control unit 200 controls driving for changing the relative position between the holding unit 2 and the light irradiation unit 3 and irradiation with light performed by the light irradiation unit 3 based on the profile determined in the profile determination step P1 and performs the formation processing of forming the composition 1c.

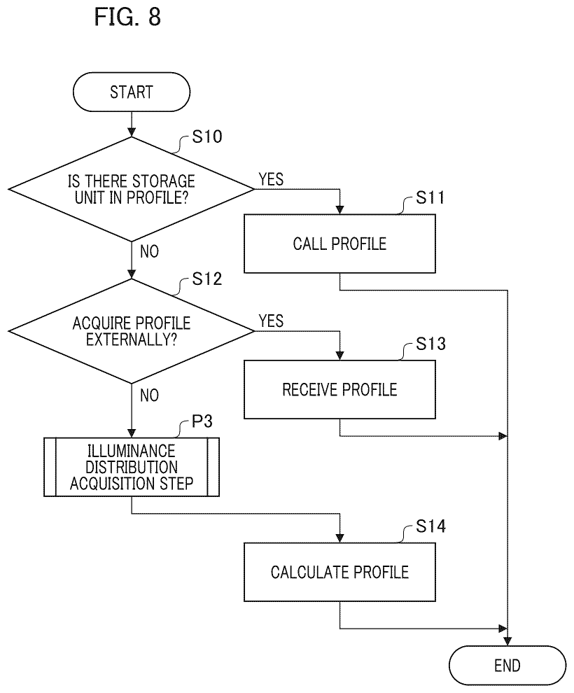

FIG. 8 is a flowchart illustrating details of the profile determination step P1. Each operation (step) as shown in this flowchart can be executed under the control of the control unit 200. First, in step S10, the control unit 200 determines whether or not a profile is stored in the storage unit. Here, in a case in which the profile is stored in the storage unit (YES), step S11 is executed, and the control unit 200 calls and acquires the profile from the storage unit and ends the profile determination step P1.

In contrast, if the profile is not stored in the storage unit (NO), it is necessary to newly acquire a profile. Therefore, in step S12, the control unit 200 determines whether or not to acquire a profile externally. In a case in which the profile is acquired externally (YES), step S13 is executed, and the control unit 200 communicates externally, receives and acquires the profile, and ends the profile determination step P1.

In contrast, in a case in which the profile is not acquired externally (NO), the process proceeds to the illuminance distribution acquisition step P3. Details of the illuminance distribution acquisition step P3 will be described below. The control unit 200, after acquiring illuminance distribution data in the illuminance distribution acquisition step P3, executes step S14, calculates and acquires a profile based on the illuminance distribution data, and ends the profile determination step P1.

As described above, the control unit 200 ends the profile determination step S11 by calling (S11), receiving (S13), and calculating (S14) the profile.

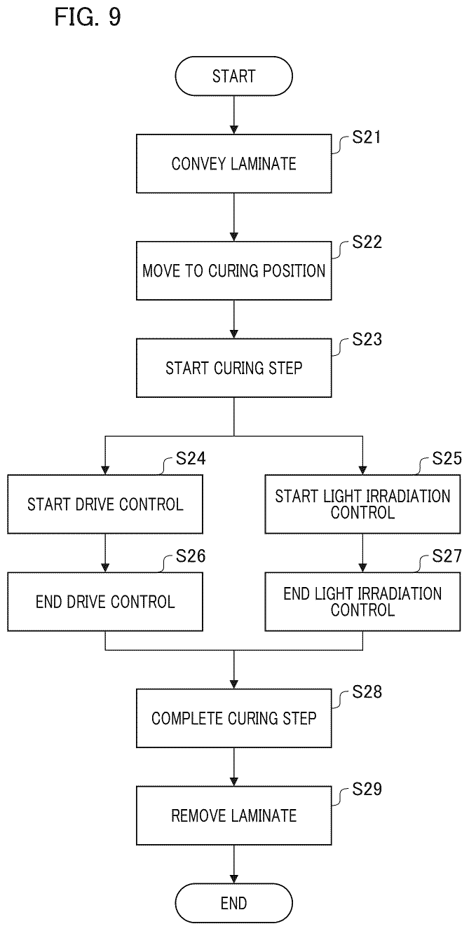

FIG. 9 is a flowchart illustrating details of the forming step P2. Each operation (step) as shown in this flowchart can be executed under the control of the control unit 200. First, in step S21, the member conveying unit 10 passes the laminate 1 to the holding unit 2 from a position (not illustrated) outside or inside the film forming apparatus 100. Then, in step S22, the drive unit 4 drives either both or one of the holding unit 2 and the light irradiation unit 3 so that the laminate 1 (holding unit 2) is in a state facing the light irradiation unit 3 (curing position).

In step S23, the curing process begins. During the curing process, the control unit 200 controls the drive unit 4 and the light irradiation unit 3 according to the profile determined in the profile determination step P1 to change the relative position between the holding unit 2 and the light irradiation unit 3 and perform light irradiation. Specifically, in step S24, the control unit 200 initiates control of the drive unit 4, controls the drive unit 4 according to the profile determined in the profile determination step P1, and changes the relative position between the holding unit 2 and the light irradiation unit 3. Then, in step S25, the control unit 200 initiates control of the light irradiation unit 3, and causes the light irradiation unit 3 to emit light at a timing according to the profile determined in the profile determination step P1. The execution of step S24 and step S25 may be performed at the same time, or any one of the steps may be executed first.

After the drive unit 4 and the light irradiation unit 3 are controlled according to the profile, in step S26 and step S27, the control of changing the relative position and the control of the light irradiation end, and, in step S28, the curing process ends. Thereby, the composition 1c on the substrate 1a is cured. Subsequently, in step S29, the holding unit 2 passes the laminate 1 to the member conveying unit 10, and the member conveying unit 10 carries out the laminate 1 to a position (not illustrated) outside or inside the film forming apparatus 100, and the forming process ends. Subsequently, for example, outside the film forming apparatus 100, the template 1b is separated (peeled off, separated) from the cured composition 1c on the substrate. Thereby, a planarized layer of the composition 1c having a flat surface can be formed on the entire substrate 1a. Note that this process is referred to as a peeling process.

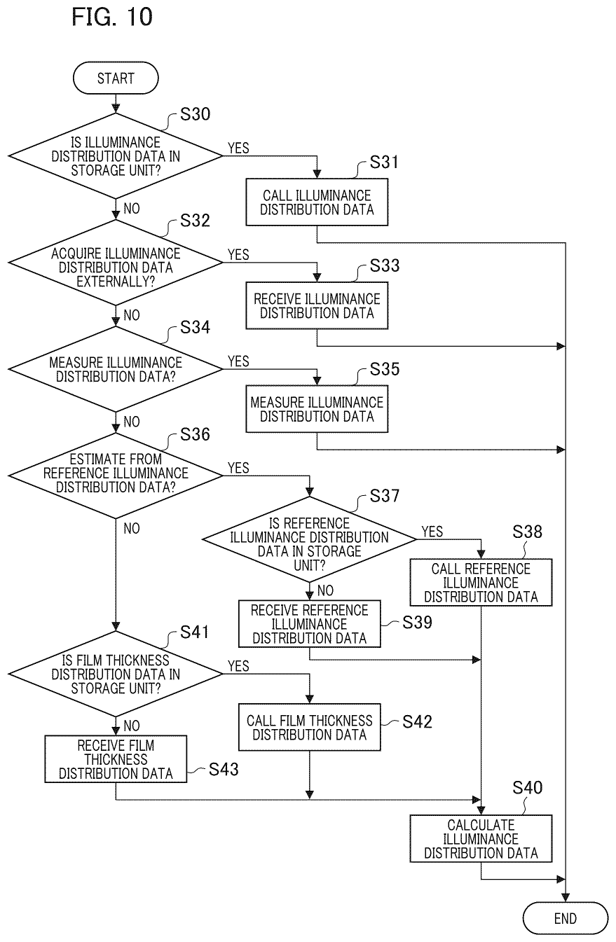

Next, the illuminance distribution acquisition step P3 will be explained in detail with reference to FIG. 10. FIG. 10 is a flowchart illustrating details of the illuminance distribution acquisition step P3. Each operation (step) as shown in this flowchart can be executed under the control of the control unit 200. The illuminance distribution acquisition step P3 is a subprocess of the profile determination step P1, and is a step for acquiring an illuminance distribution for the control unit 200 to calculate a profile in the profile determination step P1.

First, in step S30, the control unit 200 determines whether or not the illuminance distribution data is stored in the storage unit. Here, in a case in which the illuminance distribution data is stored in the storage unit (YES), step S31 is executed, and the control unit 200 acquires the illuminance distribution data by calling the illuminance distribution data from the storage unit, and ends the illuminance distribution acquisition step P3.

In contrast, in a case in which the illuminance distribution data is not stored in the storage unit (NO), it is necessary to newly acquire the illuminance distribution data. Accordingly, in step S32, the control unit 200 determines whether or not to acquire the illuminance distribution data externally. In the case of acquiring the illuminance distribution data externally (YES), step S33 is executed, and the control unit 200 communicates externally, acquires the illuminance distribution data by receiving the illuminance distribution data, and ends the illuminance distribution acquisition step P3.

In contrast, in a case in which the profile is not acquired externally (NO), in step S34, the control unit 200 determines whether or not to measure the illuminance distribution data. In a case in which the illuminance measurement unit 5 is configured in the film forming apparatus 100 and the illuminance distribution data is to be measured (YES), step S35 is executed, and the control unit 200 causes the illuminance measurement unit 5 to measure the illuminance distribution.

On the other hand, in a case in which the film forming apparatus 100 does not include the illuminance measurement unit 5 or in a case in which illuminance distribution data is not measured (NO), it is necessary to estimate the illuminance distribution data. As a method of estimating the illuminance distribution data, there is a method of estimating the illuminance distribution data by performing computational processing on reference illuminance distribution data that serves as a reference, such as an illuminance distribution measured before the start of operation of the film forming apparatus 100 and an illuminance distribution known in design. Therefore, in step S36, the control unit 200 determines whether or not to estimate the illuminance distribution from the reference illuminance distribution data.

In a case of estimating the illuminance distribution from the reference illuminance distribution data (YES), in step S37, the control unit 200 determines whether or not the reference illuminance distribution data is stored in the storage unit. In a case in which the reference illuminance distribution data is present in the storage unit of the control unit 200 (YES), step S38 is executed, and the control unit 200 calls and acquires the reference illuminance distribution data from the storage unit. In contrast, in a case in which the reference illuminance distribution data is not present in the storage unit of the control unit 200 (NO), step S39 is executed, and the control unit 200 communicates externally and receives and acquires the reference illuminance distribution data. The reference illuminance distribution data thus acquired is computationally processed in step S38, and illuminance distribution data can be acquired.

Additionally, the illuminance distribution data can also be estimated from the film thickness distribution data. Accordingly, in a case in which the illuminance distribution is estimated from the film thickness distribution data (step S36, NO), the control unit 200 determines whether or not the film thickness distribution is stored in the storage unit in S41. In a case in which the reference illuminance distribution data is stored in the storage unit of the control unit 200 (YES), step S42 is executed, and the control unit 200 acquires the film thickness distribution data by calling the film thickness distribution data from the storage unit. In contrast, in a case in which the reference illuminance distribution data is not stored in the storage unit of the control unit 200 (NO), step S43 is executed, and the control unit 200 communicates externally and acquires the film thickness distribution data by receiving the film thickness distribution data. The film thickness distribution data acquired in this manner can be processed by computational processing at S40 to acquire illuminance distribution data.

As described above, the control unit 200 acquires the illuminance distribution by calling the illuminance distribution data (S31), receiving the illuminance distribution data (S33), measuring the illuminance distribution data (S35), or calculating the illuminance distribution data (S40). Subsequently, the steps following S14 of the profile determination step P1 are executed, and the film forming apparatus 100 forms the composition 1c.

As described above, according to the present embodiment, illuminance unevenness can be reduced in the curing process, and in the composition formation process, the planarization accuracy of the formed composition can be improved.

### Second Embodiment

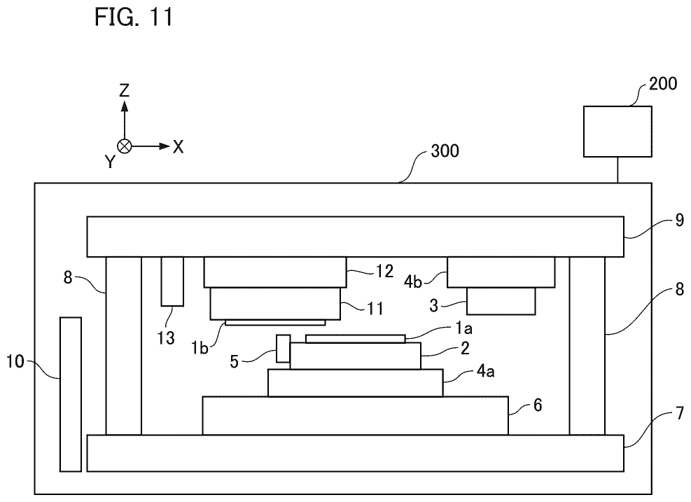

Next, a film forming apparatus according to the second embodiment will be explained with reference to FIG. 11. FIG. 11 is a schematic view illustrating a configuration example of a film forming apparatus 300 of the second embodiment. The film forming apparatus 300 includes the holding unit 2 that holds the substrate 1a, a light irradiation unit 3, the drive unit 4, the illuminance measurement unit 5, the first surface plate 6, a base 7, a first support column 8, the second surface plate 9, a mold holding unit 11 that holds the template 1b, a mold drive unit 12, and a composition supplying unit 13. Furthermore, the film forming apparatus 300 includes the member conveying unit 10 and the control unit 200. In the present embodiment, the laminate 1 is formed inside the film forming apparatus 300.

The member conveying unit 10 includes at least one conveying hand and the like, and passes the substrate 1a to the holding unit 2 and passes the template 1b to the mold holding unit 11 from a position (not illustrated) outside or inside the film forming apparatus 300. At this time, the composition 1c may or may not be disposed on the substrate 1a.

Although the holding unit 2 and the mold holding unit 11 hold the substrate 1a and the template 1b by, for example, vacuum suction, the holding means is not limited thereto. The holding means may be, for example, by electrostatic adsorption or may be holding by a clamp.

The drive unit 4 comprises at least a first drive unit 4a that connects the holding unit 2 and the first surface plate 6, and the drive unit 4 may comprise a second drive unit 4b that connects the light irradiation unit 3 and the second surface plate 9. In a case in which the second drive unit 4b is not provided, the light irradiation unit 3 is fixed to the second surface plate 9.

The first drive units 4a and 4b are configured to include, for example, actuators such as a linear motor, a rotary motor, and a voice-coil motor, a ball screw, a linear guide, a cam, a crank, and the like, and relatively drive the holding unit 2 and the light irradiation unit 3. Furthermore, the first drive unit 4a is configured to be able to move the holding unit 2 to a position immediately below the mold holding unit 11 or a composition supplying unit 13 (to be described below).

The first drive unit 4a is capable of moving the holding unit 2 that holds the substrate 1a to immediately below the composition supplying unit 13, and the composition supplying unit 13 supplies the composition 1c onto the substrate 1a. However, in a case in which the composition 1c has already been supplied to the substrate 1a, which has been passed by the member conveying unit 10, the first drive unit 4a does not need to move the holding unit 2 immediately below the composition supplying unit 13. The first drive unit 4a moves the holding unit 2 to immediately below the mold holding unit 11 in a state in which the composition 1c is supplied onto the substrate 1a.

The mold holding unit 11 is connected to the second surface plate 9 via the mold drive unit 12. The mold drive unit 12 includes an actuator such as a linear motor or a voice coil motor and is configured to be able to drive the mold holding unit 11 in the Z direction. Furthermore, the mold drive unit 12 may be configured to be movable in the X direction and the Y direction, and rotatable around the X axis, the Y axis, and the Z axis.

The mold drive unit 12 brings the holding unit 2 close to the mold holding unit 11 in a state in which the holding unit 2 is directly below the mold holding unit 11. The template 1b is then brought into contact with the composition 1c on the substrate 1a. Accordingly, the laminate 1 including the substrate 1a, the composition 1c, and the template 1b is formed.

After the laminate 1 is formed, the mold holding unit 11 releases the template 1b, and the laminate 1 becomes a state in which it is held by the holding unit 2. The first drive unit 4a moves the holding unit, which holds the laminate 1, immediately below the light irradiation unit 3, and forms the composition 1c by executing the method described in the first embodiment, specifically, executing step S23 to step S28 shown in FIG. 9.

Furthermore, in a case in which a member having a concave-convex pattern on a contact surface, such as an imprint mold, is used as the template 1b, the step may transition to the curing step while the mold holding unit 11 holds the template 1b without releasing the template 1b. Then, after step S28 as shown in FIG. 9 is completed, the peeling step is performed inside the film forming apparatus 300.

### Third Embodiment

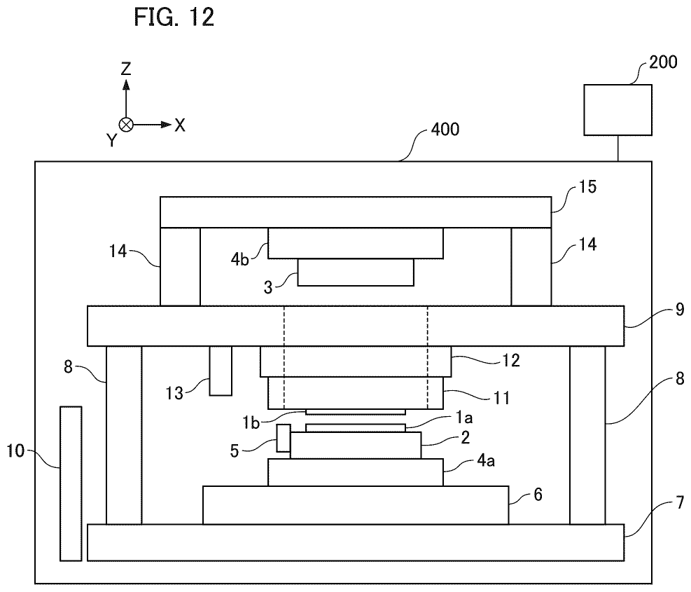

Next, a film forming apparatus according to the third embodiment will be explained with reference to FIG. 12. FIG. 12 is a schematic view illustrating a configuration example of a film forming apparatus 400 of the third embodiment. The film forming apparatus 400 includes the holding unit 2 that holds the substrate 1a, the light irradiation unit 3, a drive unit 4, the illuminance measurement unit 5, the first surface plate 6, the base 7, the first support column 8, the second surface plate 9, the mold holding unit 11 that holds the template 1b, and the mold drive unit 12. Furthermore, the film forming apparatus 400 further includes a composition supply unit 13, a second support column 14, a top plate 15, the member conveying unit 10, and the control unit 200.

The second support column 14 is fixed to the second surface plate 9 and supports the top plate 15.

The light irradiation unit 3 is connected to the top plate 15 via the second drive unit 4b. Alternatively, the light irradiation unit 3 is directly fixed to the top plate 15 without using the second drive unit 4b. The light irradiation unit 3 is located immediately above the mold holding unit 11, and light emitted from the light irradiation unit 3 passes through the second surface plate 9, the mold drive unit 12, and the mold holding unit 11, and reaches the template 1b or the laminate 1.

In this embodiment, the laminate 1 is formed inside the film forming apparatus 400 by the similar method as in the second embodiment, and the composition 1c is formed.

### <Specific Application Example of Film Forming Apparatus>

The film forming apparatus as described above can be used as a planarization apparatus that performs planarization processing to form a planarization film made of a curable composition on the substrate. In the planarization apparatus, a member having a flat surface (also referred to as a superstrate) is used to form a planarization layer on a substrate. The base pattern on the substrate has a concave-convex profile caused by the pattern formed in the previous process, and, in particular, with the recent trend of multi-layer structuring in memory elements, process substrates having a level difference of around 100 nm have also emerged. The level difference caused by the gentle waviness of the entire substrate can be corrected by a focus tracking function of a scanning exposure apparatus used in a photo step. However, unevenness with a fine pitch that fall within the exposure slit area of the exposure apparatus directly consume the Depth Of Focus (DOF) of the exposure apparatus. As a conventional method for smoothing the base pattern of a substrate, a method of forming a planarization layer such as Spin On Carbon (SOC) or Chemical Mechanical Polishing (CMP) is used. However, in the prior art, there is a drawback in which sufficient planarization performance cannot be obtained, and the difference in unevenness of the base is likely to increase further due to future multi-layering. To solve this problem, in the planarization apparatus, planarization processing is performed collectively on the entire substrate surface by supplying the composition to the entire substrate surface and causing the composition on the substrate and a member having a planar surface (also referred to as a superstrate) to contact each other.

Additionally, the film forming apparatus as described above may be an imprint apparatus that transfers a pattern of a mold to an imprint material by bringing the imprint material, which is a composition on a substrate, into contact with the mold having a concave-convex pattern. In the imprint apparatus, imprinting can be performed for each of a plurality of shot regions formed on a substrate. Alternatively, in the imprint apparatus, imprinting (that is, contact) can be performed collectively for a plurality of shot regions of the substrate (on the entire substrate, or in units of one or more rows of shot regions).

### Embodiment of Article Manufacturing Method

The pattern of the cured product formed by using the imprint apparatus is used permanently for at least a part of various articles or temporarily in a case in which various articles are manufactured. The article is, for example, an electric circuit element, an optical element, a MEMS, a recording element, a sensor, a mold, and the like. Examples of the electric circuit element include volatile or nonvolatile semiconductor memories such as a DRAM, an SRAM, a flash memory, and an MRAM, and semiconductor elements such as an LSI, a CCD, an image sensor, and an FPGA. Examples of the mold include a mold for imprinting.

The pattern of the cured product is directly used as at least a part of the configuration components of the above-mentioned article, or temporarily used as a resist mask. After etching or ion implantation is performed in the substrate processing step, the resist mask is removed.

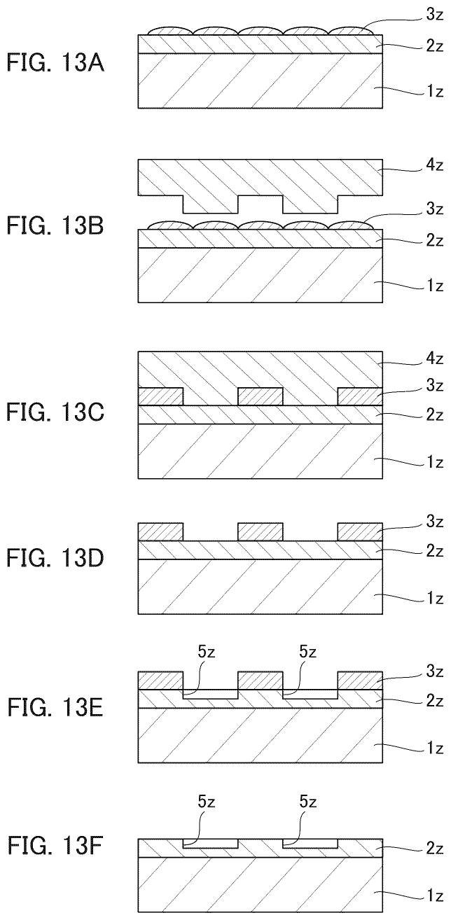

Next, a specific method for manufacturing an article will be explained. As shown in FIG. 13A, a substrate 1z, such as a silicon wafer with a material to be processed 2z, such as an insulator, formed on a surface thereof, is prepared. Subsequently, an imprint material 3z is applied to the surface of the material to be processed 2z using, for example, an inkjet method. Here, a state in which the imprint material 3z in the form of a plurality of droplets is applied onto the substrate is shown.

As shown in FIG. 13B, a mold 4z for imprinting is positioned to face the imprint material 3z on the substrate, wherein the side of the mold 4z on which the concave-convex pattern is formed faces toward the imprint material 3z. As shown in FIG. 13C, the substrate 1z to which the imprint material 3z has been applied and the mold 4z are brought into contact with each other, and a pressure is applied. The imprint material 3z is filled in a gap between the mold 4z and the material to be processed 2z. In this state, when light is irradiated through the mold 4z as curing energy, the imprint material 3z is cured.

As shown in FIG. 13D, after the imprint material 3z is cured, when the mold 4z and the substrate 1z are separated, a cured product pattern of the imprint material 3z is formed on the substrate 1z. The cured product pattern corresponds such that a concave portion of the mold corresponds to a convex portion of the cured product and a convex portion of the mold corresponds to a concave portion of the cured product, that is, the concave-convex pattern of the mold 4z is transferred to the imprint material 3z.

As shown in FIG. 13E, when etching is performed using the pattern of the cured product as an etching-resistant mask, a portion in which the cured product does not exist or remains thin is removed from the surfaces of the material to be processed 2z to form a groove 5z. As shown in FIG. 13F, when the pattern of the cured product is removed, a product with a groove 5z formed on the surface of the material to be processed 2z can be obtained. Although the pattern of the cured product is removed here, the pattern may be used as, for example, a film for interlayer insulation included in a semiconductor element and the like, that is, a configuration member of an article, without being removed even after processing.

Note that although an example in which a mold for transferring a circuit pattern provided with a concave-convex pattern is used as the mold 4z has been described, the mold 4z may be a member having a planar portion without a concave-convex pattern (planar template).

### OTHER EMBODIMENTS

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

This application claims the benefit of Japanese Patent Application No. 2024-068027, filed on Apr. 19, 2024, which is hereby incorporated by reference wherein in its entirety.

What is claimed is:

1. A film forming apparatus that forms a film of a curable composition on a substrate, comprising:
a holding unit configured to hold the substrate;
a light irradiation unit configured to irradiate light that cures the curable composition;
a drive unit configured to drive so as to change a relative position between the holding unit and the light irradiation unit; and
a control unit configured to control driving of the drive unit and timing at which the light irradiation unit irradiates the light based on an illuminance distribution of the light in a region in which the light is irradiated by the light irradiation unit.

2. The film forming apparatus according to claim 1,
wherein a process of forming the film includes a curing step that cures the curable composition by the light from the light irradiation unit, and
wherein control of driving of the drive unit and timing at which the light irradiation unit irradiates the light are performed in the curing step.

3. The film forming apparatus according to claim 1, wherein the control unit controls driving of the drive unit and timing at which the light irradiation unit irradiates the light so that a difference in an integrated exposure amount between an arbitrary first region and an arbitrary second region that is different from the first region, among the regions in which the light is irradiated, becomes equal to or less than a predetermined value.

4. The film forming apparatus according to claim 1, further comprising an illuminance measurement unit configured to measure the illuminance distribution.

5. The film forming apparatus according to claim 1, wherein the driving includes causing at least one of the holding unit and the light irradiation unit to perform translational motion.

6. The film forming apparatus according to claim 5, wherein the translational motion includes a circular or elliptical motion.

7. The film forming apparatus according to claim 1, wherein the driving includes causing at least one of the holding unit and the light irradiation unit to perform rotational motion.

8. The film forming apparatus according to claim 1, wherein the driving includes a periodic motion.

9. The film forming apparatus according to claim 1, wherein the control unit causes the light irradiation unit to intermittently emit the light.

10. The film forming apparatus according to claim 1, wherein the holding unit further holds a template that is in contact with the curable composition on the substrate.

11. A film forming method of forming a film of a curable composition on a substrate, comprising:
holding the substrate by a holding unit;
irradiating light that cures the curable composition from a light irradiation unit; and
controlling driving that changes a relative position between the holding unit and the light irradiation unit and a timing at which the light irradiation unit irradiates the light based on an illuminance distribution of the light in a region in which the light is irradiated by the light irradiation unit.

12. The film forming method according to claim 11,
wherein processing to form the film includes a curing step of curing the curable composition by the light from the light irradiation unit, and
wherein control of driving that changes the relative position and a timing at which the light is irradiated is performed in the curing step.

13. The film forming method according to claim 11, wherein control of driving that changes the relative position and timing at which the light is irradiated performs control so that a difference in integrated exposure amount between an arbitrary first region and an arbitrary second region different from the first region among the region in which the light is irradiated becomes equal to or less than a predetermined value.

14. The film forming method according to claim 11, further comprising a step of measuring the illuminance distribution by an illuminance measurement unit before processing to form the film is executed.

15. The film forming method according to claim 11, further comprising a step of estimating the illuminance distribution from measurement results of a film thickness distribution of the film formed by previous processing.

16. The film forming method according to claim 11, further comprising determining content of the driving based on an arrangement of a light source of the light irradiation unit.

17. A manufacturing method of an article, comprising:
a step of forming a curable composition on a substrate by using a film forming apparatus that forms a film of a curable composition on a substrate;
a step of processing the substrate on which the curable composition is formed, and
a step of manufacturing an article from the processed substrate,
wherein the film forming apparatus comprises:
a holding unit configured to hold the substrate;
a light irradiation unit configured to irradiate light that cures the curable composition,
a drive unit configured to drive so as to change a relative position between the holding unit and the light irradiation unit; and
a control unit configured to control driving of the drive unit and timing at which the light irradiation unit irradiates the light based on an illuminance distribution of the light in a region in which the light is irradiated by the light irradiation unit.
